(19) United States
(12) Patent Application Publication
(10) Pub. No.: US 2025/0255125 A1
(43) Pub. Date: Aug. 7, 2025

(54) DISPLAY DEVICE

(71) Applicant: Samsung Display Co., LTD., Yongin-si (KR)

(72) Inventors: Dong Hee SHIN, Yongin-si (KR); Sun Kwun SON, Yongin-si (KR); Sang Yong NO, Yongin-si (KR)

(21) Appl. No.: 18/951,433

(22) Filed: Nov. 18, 2024

(30) Foreign Application Priority Data
Feb. 7, 2024 (KR) 10-2024-0019099

(51) Int. Cl. H10K 59/131; G09G 3/3233; H10K 59/95

(52) U.S. Cl. CPC H10K 59/131; G09G 3/3233; H10K 59/95; G09G 2300/0426; G09G 2300/0819; G09G 2300/0842; G09G 2300/0861; G09G 2310/08

(57) ABSTRACT

A display device includes: a light-emitting element to receive a data voltage from a data line; a light-receiving element to provide a sensing current to a readout line; a first readout connection line and a first data connection line; a second readout connection line; and a first electrode pattern. The readout line, the first readout connection line, and the second readout connection line are connected to each other at a same electrical node, and the data line and the first data connection line are connected to each other at a same electrical node. The second readout connection line overlaps with at least one of the data line or the first data connection line in a first area, and the first electrode pattern is located between at least one of the data line or the first data connection line and the second readout connection line in the first area.

### CROSS-REFERENCE TO RELATED APPLICATION

The present application claims priority to and the benefit of Korean Patent Application No. 10-2024-0019099, filed in the Korean Intellectual Property Office on Feb. 7, 2024, the entire disclosure of which is incorporated by reference herein.

### BACKGROUND

### 1. Field

Aspects of embodiments of the present disclosure relate to a display device.

### 2. Description of the Related Art

As information technology has developed, the importance of a display device, which is a connection medium between a user and information, has been highlighted. Accordingly, the use of display devices, such as a liquid crystal display device, an organic light emitting display device, and the like, has been increasing.

The display device displays an image using pixels. In addition, the display device may sense the user's fingerprint using a plurality of optical sensors, and may perform a user authentication function. Recently, an in-cell type display panel is being manufactured in which the pixels and the optical sensors are formed in the same process.

The above information disclosed in this Background section is for enhancement of understanding of the background of the present disclosure, and therefore, it may contain information that does not constitute prior art.

### SUMMARY

One or more embodiments of the present disclosure may be directed to a display device that may minimize or reduce a parasitic capacitance between a readout line of an optical sensor and other signal lines.

According to one or more embodiments of the present disclosure, a display device includes: a pixel including a light-emitting element configured to receive a data voltage from a data line, and emit light having a luminance based on the data voltage; an optical sensor including a light-receiving element, and configured to provide a sensing current generated based on an amount of light received by the light-receiving element to a readout line; a plurality of first connection lines extending in a first direction, and including a first readout connection line and a first data connection line; a plurality of second connection lines extending in a second direction different from the first direction, and including a second readout connection line; and a first electrode pattern. The readout line, the first readout connection line, and the second readout connection line are connected to each other at a same electrical node, and the data line and the first data connection line are connected to each other at a same electrical node. The second readout connection line overlaps with at least one of the data line or the first data connection line in a first area, and the first electrode pattern is located between at least one of the data line or the first data connection line and the second readout connection line in the first area.

In an embodiment, the first electrode pattern may be configured to receive a first power voltage supplied to the pixel.

In an embodiment, the first electrode pattern may be integral with a first power line connected to the pixel.

In an embodiment, the first electrode pattern may not be connected to the optical sensor.

In an embodiment, the pixel and the optical sensor may be connected to a same scan line.

In an embodiment, the display device may further include a second electrode pattern, and the plurality of second connection lines may further include a second data connection line. The second data connection line may be connected to the data line and the first data connection line at a same electrical node, and the second data connection line may overlap with at least one of the data line or the first data connection line in a second area. The second electrode pattern may be located between at least one of the data line or the first data connection line and the second data connection line in the second area.

In an embodiment, the second electrode pattern may have an island shape that may not be connected to other electrodes.

In an embodiment, a voltage may not be supplied to the second electrode pattern.

In an embodiment, the first data connection line may have a first interval from a closet data line thereto in the second direction; the first readout connection line may have a second interval from a closet data line thereto in the second direction; and the second interval may be greater than the first interval.

In an embodiment, the first readout connection line may be located between two adjacent pixels configured in a mirror-symmetrical layout.

According to one or more embodiments of the present disclosure, a display device includes: a pixel including a light-emitting element configured to receive a data voltage from a data line, and emit light having a luminance based on the data voltage; an optical sensor including a light-receiving element, and configured to provide a sensing current generated based on an amount of light received by the light-receiving element to a readout line; a plurality of first connection lines extending in a first direction, and including a first readout connection line and a first data connection line; and a plurality of second connection lines extending in a second direction different from the first direction, and including a second readout connection line. The readout line, the first readout connection line, and the second readout connection line are connected to each other at a same electrical node, and the data line and the first data connection line are connected to each other at a same electrical node. The first data connection line has a first interval from a closet data line thereto in the second direction, the first readout connection line has a second interval from a closet data line thereto in the second direction, and the second interval is greater than the first interval.

In an embodiment, the first readout connection line may be located between two adjacent pixels configured in a mirror-symmetrical layout.

In an embodiment, the display device may further include a first electrode pattern. The second readout connection line may overlap with at least one of the data line or the first data connection line in a first area, and the first electrode pattern may be located between at least one of the data line or the first data connection line and the second readout connection line in the first area.

In an embodiment, the first electrode pattern may be configured to receive a first power voltage supplied to the pixel.

In an embodiment, the first electrode pattern may be integral with a first power line connected to the pixel.

In an embodiment, the first electrode pattern may not be connected to the optical sensor.

In an embodiment, the pixel and the optical sensor may be connected to a same scan line.

In an embodiment, the display device may further include a second electrode pattern, and the plurality of second connection lines may further include a second data connection line. The second data connection line may be connected to the data line and the first data connection line at a same electrical node, the second data connection line may overlaps with at least one of the data line or the first data connection line in a second area, and the second electrode pattern may be located between at least one of the data line or the first data connection line and the second data connection line in the second area.

In an embodiment, the second electrode pattern may have an island shape that may not be connected to other electrodes.

In an embodiment, a voltage may not be supplied to the second electrode pattern.

According to some embodiments of the present disclosure, the display device may minimize or reduce a parasitic capacitance between a readout line of an optical sensor and other signal lines.

However, the present disclosure is not limited to the above aspects and features, and the above and other aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings.

FIG. 1 and FIG. 2 are drawings illustrating a display device according to an embodiment of the present disclosure.

FIG. 3 is a drawing illustrating a pixel according to an embodiment of the present disclosure.

FIG. 4 is a drawing illustrating an optical sensor according to an embodiment of the present disclosure.

FIG. 5 is a drawing illustrating a method of driving a pixel and an optical sensor according to an embodiment of the present disclosure.

FIG. 6A and FIG. 6B are drawings illustrating a relationship between pads, connection lines, and signal lines according to one or more embodiments of the present disclosure.

FIG. 7 is a drawing illustrating a stacked structure of a display area of a display panel.

FIGS. 8-17 are drawings illustrating a plan layout of a first connection area according to one or more embodiments of the present disclosure.

FIG. 18 illustrates a cross-sectional view taken along the line I-I′ of FIG. 16.

FIG. 19 is a drawing illustrating a plan layout of a second connection area according to an embodiment of the present disclosure.

FIG. 20 illustrates a cross-sectional view taken along the line II-II′ of FIG. 19.

FIG. 21 is a drawing illustrating an example connection between a first data connection line and a second data connection line.

FIG. 22 is a drawing illustrating an example connection between a first readout connection line and a second readout connection line.

FIG. 23 illustrates a block diagram of an electronic device according to one or more embodiments of the present disclosure.

FIG. 24 illustrates an example in which the electronic device of FIG. 23 is implemented as a smart phone.

FIG. 25 illustrates an example in which the electronic device of FIG. 23 is implemented as a tablet PC.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

The expressions “equal to” or “the same as” as used in the present disclosure may mean “substantially equal to” or “substantially the same as”. In other words, it may be the same or equal to each other while taking into consideration various tolerances as would be understood by those having ordinary skill in the art to mean the same or equal to each other. Further, other expressions used herein may be expressions from which “substantially” is omitted.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

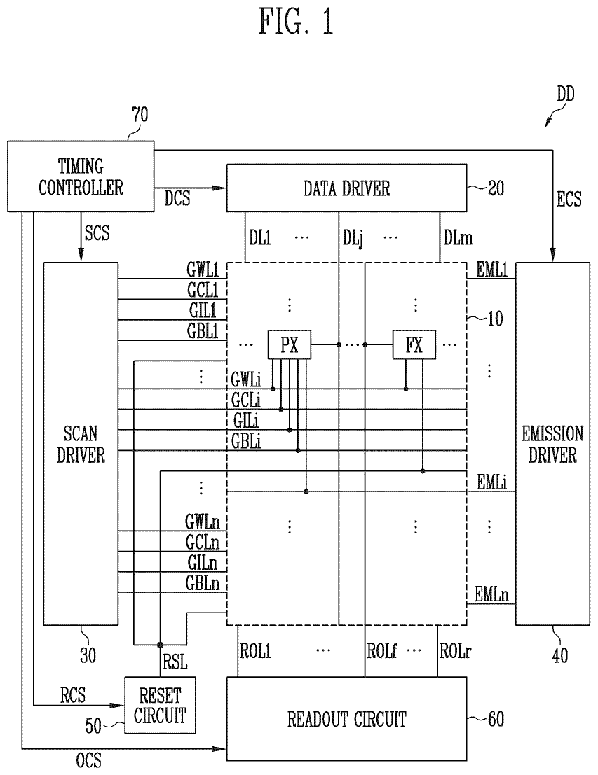

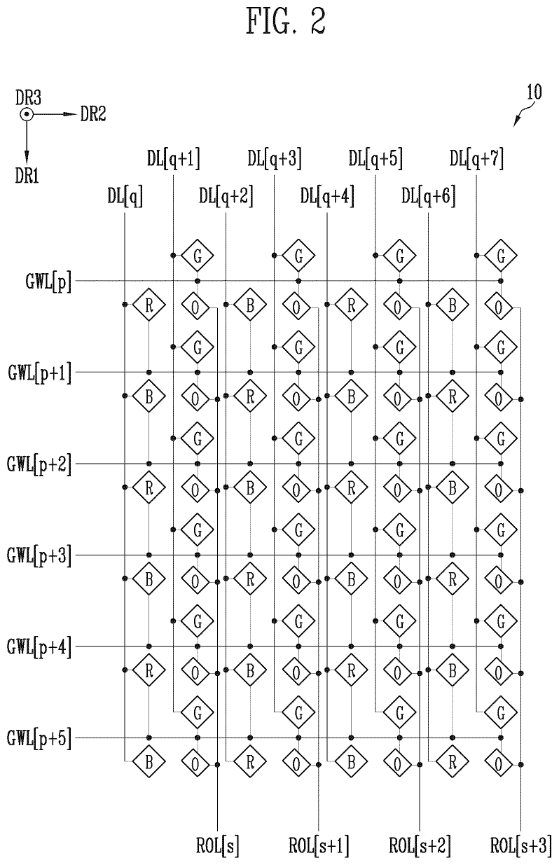

FIG. 1 and FIG. 2 are drawings illustrating a display device according to an embodiment of the present disclosure.

Referring to FIG. 1, a display device DD according to an embodiment of the present disclosure may include a display panel 10, a data driver 20, a scan driver 30, an emission driver 40, a reset circuit 50, a readout circuit 60, and a timing controller 70.

The timing controller 70 may receive grays (e.g., grayscales) and timing signals for each frame period from a processor. The processor may correspond to (e.g., may include) at least one of a graphics processing unit (GPU), a central processing unit (CPU), and/or an application processor (AP). The timing signals may include a vertical synchronization signal, a horizontal synchronization signal, a data enable signal, and the like.

Each cycle of the vertical synchronization signal may correspond to each frame period. Each cycle of the horizontal synchronization signal may correspond to each horizontal period. The grayscales may be supplied in units of a horizontal line in each horizontal period in response to a pulse of an enable level of the data enable signal. The horizontal line may refer to pixels connected to the same scan line and emission line as each other (e.g., a pixel row).

The timing controller 70 may generate a first control signal SCS, a second control signal ECS, a third control signal DCS, a fourth control signal RCS, and a fifth control signal OCS based on the received grayscales and timing signals. The first control signal SCS may be supplied to the scan driver 30, the second control signal ECS may be supplied to the emission driver 40, the third control signal DCS may be supplied to the data driver 20, the fourth control signal RCS may be supplied to the reset circuit 50, and the fifth control signal OCS may be supplied to the readout circuit 60. The timing controller 70 may rearrange (e.g., render) and correct the grayscales and supply them to the data driver 20.

The display panel 10 may include pixels PX connected to data lines (e.g., DL1, . . . , DLj, . . . , DLm), scan lines (e.g., GWL1, . . . , GWLi, . . . , GWLn, GCL1, . . . , GCLi, . . . ,GCLn, GIL1, . . . , GILi, . . . , GILn, GBL1, . . . , GBLi, . . . , GBLn), and emission lines (e.g., EML1, . . . , EMLi, . . . , EMLn). Each of the pixels PX may include a light emitting element that receives a data voltage from a corresponding data line, and emits light having a luminance based on the data voltage. In addition, the display panel 10 may include optical sensors FX connected to first scan lines (e.g., GWL1, . . . , GWLi, . . . , GWLn), a reset line RSL, and readout lines (e.g., ROL1, . . . , ROLf, . . . , ROLr). Each of the optical sensors FX may include a light-receiving element, and may provide a sensing current generated based on an amount of light received by the light-receiving element to a corresponding readout line. Here, m, n, and r may be integers greater than 1.

The data driver 20 may receive the grayscales and the third control signal DCS from the timing controller 70. For example, the third control signal DCS may include a source start signal, a clock signal, and the like. For example, the data driver 20 may sample grayscales while shifting the source start signal based on the clock signal, and may apply data voltages corresponding to the sampled grayscales to the data lines DL1 to DLm in units of pixel rows.

The scan driver 30 may receive the first control signal SCS from the timing controller 70. The first control signal SCS may include a clock signal, a scan start signal, and the like. The scan driver 30 may supply scan signals to the scan lines (e.g., GWL1, . . . , GWLi, . . . , GWLn, GCL1, . . . , GCLi, . . . , GCLn, GIL1, . . . , GILi, . . . , GILn, GBL1, . . . , GBLi, . . . , GBLn) in response to the first control signal SCS.

FIG. 1 illustrates an embodiment in which the scan lines (e.g., GWL1, . . . , GWLi, . . . , GWLn, GCL1, . . . , GCLi, . . . , GCLn, GIL1, . . . , GILi, . . . , GILn, GBL1, . . . , GBLi, . . . , GBLn) are connected to one scan driver 30, but the present disclosure is not limited thereto. For example, the scan driver 30 may include a first sub-scan driver connected to the first scan lines (e.g., GWL1, . . . , GWLi, . . . , GWLn), a second sub-scan driver connected to the second scan lines (e.g., GCL1, . . . , GCLi, . . . , GCLn), a third sub-scan driver connected to the third scan lines (e.g., GIL1, . . . , GILi, . . . , GILn), and a fourth sub-scan driver connected to the fourth scan lines (e.g., GBL1, . . . , GBLi, . . . , GBLn). In another example, the scan driver 30 may include a first sub-scan driver connected to the scan lines (e.g., GWL1, . . . , GWLi, . . . , GWLn, GBL1, . . . , GBLi, . . . , GBLn) and a second sub-scan driver connected to the scan lines (e.g., GCL1, . . . , GCLi, . . . , GCLn, GIL1, . . . , GILi, . . . , GILn).

The scan driver 30 or each sub-scan driver may sequentially supply scan signals having a pulse of a turn-on level to corresponding scan lines. The scan driver 30 or each sub-scan driver may include scan stages configured in the form of a shift register. The scan driver 30 or each sub-scan driver may generate the scan signals through a suitable method of sequentially transmitting a scan start signal, which is a pulse type of a turn-on level, to a next scan stage according to a control of the clock signal.

The emission driver 40 may receive the second control signal ECS from the timing controller 70. The second control signal ECS may include a clock signal, a emission stop signal, and the like. The emission driver 40 may supply an emission signal to emission lines EML1 to EMLn in response to the second control signal ECS.

The emission driver 40 may sequentially supply the emission signals at a turn-off level pulse to the emission lines EML1 to EMLn. The emission driver 40 may include emission stages configured in a form of a shift register. The emission driver 40 may generate the emission signals by sequentially transmitting a emission stop signal having a form of a turn-off level pulse to a next emission stage depending on a control of a clock signal.

FIG. 1 illustrates an embodiment in which the scan driver 30 and the emission driver 40 are separately provided, but the present disclosure is not limited thereto. For example, the scan driver 30 and the emission driver 40 may be integrated with each other into one driving circuit or one driving module.

The reset circuit 50 may receive the fourth control signal RCS from the timing controller 70. The reset circuit 50 may apply a reset signal to the reset line RSL in response to the fourth control signal RCS. The reset line RSL may be commonly connected to all of the optical sensors FX of the display panel 10. In other words, a common reset signal may be transmitted to all of the optical sensors FX. In another embodiment, the reset circuit 50 may be connected to a plurality of optical sensors FX through a plurality of reset lines. In this case, a plurality of different reset signals may be transmitted to different optical sensors FX.

For sensing, at least some of the pixels PX disposed in a selected area may emit light in a sensing pattern. The sensing pattern may be a single color pattern (e.g., a red pattern or a green pattern). The optical sensors FX may generate sensing signals corresponding to an amount of received light. Pixels PX disposed outside the selected area may continuously display an image (e.g., an existing image or a current image). Because the sensing pattern of the pixels PX disposed in the selected area covered by a finger may not be visually recognized by the user, the user may continue to watch the image (e.g., the existing image or the current image).

The readout circuit 60 may receive the fifth control signal OCS from the timing controller 70. The readout circuit 60 may provide sensing information based on sensing signals received from the readout lines ROL1 to ROLr in response to the fifth control signal OCS. The sensing information may be variously configured according to a mode of the display device DD. For example, the sensing information may include (e.g., may be) fingerprint image information, Photoplethysmo (PPG) information, or the like.

The processor or the timing controller 70 may perform a user authentication function or the like using the sensing information provided from the readout circuit 60.

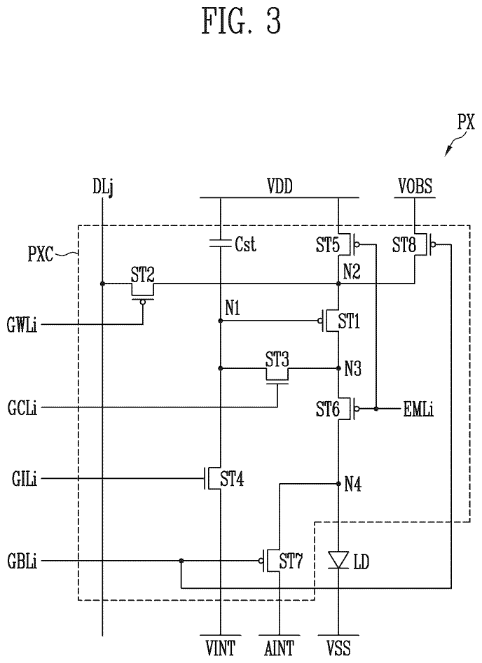

Referring to FIG. 2, a connection relationship between the first scan lines GWL[p] to GWL[p+5], the data lines DL[q] to DL[q+7], the readout lines ROL[s] to ROL[s+3], the pixels PX, and the optical sensors FX is illustrated in the display panel 10 as an example. A connection relationship between the other scan lines GCL1 to GCLn, GIL1 to GILn, and GBL1 to GBLn, the emission lines EML1 to EMLn, and the pixels PX shown in FIG. 1 will be described in more detail below with reference to FIG. 3.

The pixels PX may be connected to the first scan lines GWL[p] to GWL[p+5], and may include light emitting elements R, G, and B. The first scan lines GWL[p] to GWL[p+5] may be disposed to be parallel or substantially parallel to each other in a first direction DR1. The first scan lines GWL[p] to GWL[p+5] may extend in a second direction DR2. Here, p may be an integer larger than zero and less than or equal to n. In addition, the pixels PX may be connected to the data lines DL[q] to DL[q+7]. The data lines DL[q] to DL[q+7] may extend in the first direction DR1, and may be disposed parallel to or substantially parallel to each other in the second direction DR2. Here, q may be an integer greater than zero and less than or equal to m.

Each of the light emitting elements R, G, and B of the pixels PX may emit one of a light of a first color, a light of a second color, and/or a light of a third color. The first color, the second color, and the third color may be different colors from each other. For example, the first color may be one color of red, green, or blue, the second color may be another color of red, green, or blue excluding the first color, and the third color may be the remaining color of red, green, or blue excluding the first and second colors. In addition, magenta, cyan, and yellow may be used instead of red, green, and blue as the first to third colors. Hereinafter, for convenience, a case in which the first color is red, the second color is green, and the third color is blue will be described in more detail as a representative example.

In the present embodiment, the light emitting elements R, G, and B of the pixels PX are illustrated as disposed in a diamond shape arrangement (e.g., in a DIAMOND PIXEL™ structure or a PENTILE® structure, PENTILE® being a duly registered trademark of Samsung Display Co., Ltd.), as an example. However, the present disclosure is not limited to the connection relationships of the illustrated first scan lines GWL[p] to GWL[p+5], the data lines DL[q] to DL[q+7], and the pixels PX, and may be variously modified as needed or desired. For example, the pixels PX including the light emitting elements R and B of the first color and the third color may be connected to the same data lines DL[q], DL[q+2], DL[q+4], or DL[q+6] as each other, and the pixels PX including the light emitting elements G of the second color may be connected to independent data lines DL[q+1], DL[q+3, DL[q+5], or DL[q+7]. The data lines DL[q], DL[q+2], DL[q+4], or DL[q+6] connected to the pixels PX including the light emitting elements R and B of the first color and the third color and the data lines DL[q+1], DL[q+3], DL[q+5], or DL[q+7] connected to the pixels PX including the light emitting elements G of the second color may be alternately disposed along the second direction DR2.

The optical sensors FX including light-receiving elements O may be connected to the first scan lines GWL[p] to GWL[p+5] and the readout lines ROL[s] to ROL[s+3]. The readout lines ROL[s] to ROL[s+3] may extend in the first direction DR1, and may be disposed parallel to or substantially parallel to each other in the second direction DR2.

FIG. 3 is a drawing illustrating a pixel according to an embodiment of the present disclosure.

In FIG. 3, a pixel PX disposed in an i-th pixel row and a j-th pixel column from among the plurality of pixels PX is illustrated as a representative example. A pixel row may indicate the pixels PX that are connected to the same scan lines and emission lines as each other, and a pixel column may indicate the pixels PX that are connected to the same data line as each other. Here, i is an integer of 1 or more and n or less, and j is an integer of 1 or more and m or less.

Referring to FIG. 3, the pixel PX may include a pixel circuit PXC and a light emitting element LD. The pixel circuit PXC may include pixel transistors ST1 to ST8 and a storage capacitor Cst.

A gate electrode of the first pixel transistor ST1 (e.g., a driving transistor) may be connected to a first node N1, a first electrode of the first pixel transistor ST1 may be connected to a second node N2, and a second electrode of the first pixel transistor ST1 may be connected to a third node N3. The first pixel transistor ST1 may control a driving current flowing from a first power voltage VDD to a second power voltage VSS via the light emitting element LD corresponding to (e.g., according to or based on) a voltage of the first node N1.

A first electrode of the second pixel transistor ST2 (e.g., a switching transistor) may be connected to the data line DLj, a second electrode of the second pixel transistor ST2 may be connected to the second node N2, and a gate electrode of the second pixel transistor ST2 may be connected to the first scan line GWLi. The second pixel transistor ST2 may be turned on when the first scan signal at the turn-on level is supplied to the first scan line GWLi, and may electrically connect the data line DLj and the second node N2 to each other.

A first electrode of the third pixel transistor ST3 (e.g., a diode connection transistor) may be connected to the first node N1, a second electrode of the third pixel transistor ST3 may be connected to the third node N3, and a gate electrode of the third pixel transistor ST3 may be connected to the second scan line GCLi. The third pixel transistor ST3 may be turned on when the second scan signal at the turn-on level is supplied to the second scan line GCLi, and may electrically connect the gate electrode and the second electrode of the first pixel transistor ST1 to each other. In other words, when the third pixel transistor ST3 is turned on, the first pixel transistor ST1 may be diode-connected.

A first electrode of the fourth pixel transistor ST4 (e.g., a gate initialization transistor) may be connected to the first node N1, a second electrode of the fourth pixel transistor ST4 may be connected to a first initialization voltage line to which a first initialization voltage VINT is applied, and a gate electrode of the fourth pixel transistor ST4 may be connected to the third scan line GILi. The fourth pixel transistor ST4 may be turned on when the third scan signal at the turn-on level is supplied to the third scan line GILi, and may supply the first initialization voltage VINT to the first node N1.

A first electrode of the fifth pixel transistor ST5 (e.g., a first emission transistor) may be connected to the first power line to which the first power voltage VDD is applied, a second electrode of the fifth pixel transistor ST5 may be connected to the second node N2, and a gate electrode of the fifth pixel transistor ST5 may be connected to an emission line EMLi. The fifth pixel transistor ST5 may be turned off when a turn-off level emission signal is supplied to the emission line EMLi, and may be turned on in other cases.

A first electrode of the sixth pixel transistor ST6 (e.g., a second emission transistor) may be connected to the third node N3, a second electrode of the sixth pixel transistor ST6 may be connected to a fourth node N4, and a gate electrode of the sixth pixel transistor ST6 may be connected to the emission line EMLi. The sixth pixel transistor ST6 may be turned off when the turn-off level emission signal is supplied to the emission line EMLi, and may be turned on in other cases. The pixel PX may emit light in response to the emission signal received from the emission line EMLi. In other words, the emission timing of the pixel PX may be determined corresponding to the emission signal received from the emission line EMLi.

A first electrode of the seventh pixel transistor ST7 (e.g., an anode initialization transistor) may be connected to the fourth node N4, a second electrode of the seventh pixel transistor ST7 may be connected to a second initialization voltage line to which a second initialization voltage AINT is applied, and a gate electrode of the seventh pixel transistor ST7 may be connected to the fourth scan line GBLi. The seventh pixel transistor ST7 may be turned on when the fourth scan signal at the turn-on level is supplied to the fourth scan line GBLi, and may supply the second initialization voltage AINT to the fourth node N4. For example, the i-th fourth scan line GBLi may be the same as the (i-1)-th first scan line GWLi.

A first electrode of the eighth pixel transistor ST8 (e.g., a bias transistor) may receive a bias voltage VOBS, a second electrode of the eighth pixel transistor ST8 may connected to the second node N2, and a gate electrode of the eighth pixel transistor ST8 may be connected to the fourth scan line GBLi. The eighth pixel transistor ST8 may be turned on when the fourth scan signal at the turn-on level is supplied to the fourth scan line GBLi, and may supply the bias voltage VOBS to the second node N2.

Some transistors ST1, ST2, ST5, ST6, ST7, and ST8 from among the pixel transistors ST1 to ST8 may be P-type transistors, and other transistors ST3 and ST4 may be N-type transistors, but the present disclosure is not limited thereto. For example, each of the pixel transistors ST1 to ST8 may be a P-type transistor or an N-type transistor.

The P-type transistors may be polysilicon semiconductor transistors. In the polysilicon semiconductor transistor, a channel of a semiconductor layer may include a polysilicon semiconductor. For example, the polysilicon semiconductor transistor may be a low temperature poly-silicon (LTPS) thin film transistor. The polysilicon semiconductor transistor has high electron mobility, and thus, has fast driving characteristics.

The N-type transistors may be oxide semiconductor transistors. In the oxide semiconductor transistor, a channel of a semiconductor layer may include an oxide semiconductor. For example, the oxide semiconductor transistor may be a low temperature polycrystalline oxide (LTPO) thin film transistor. The oxide semiconductor transistor has lower charge mobility than that of the polysilicon semiconductor transistor. Therefore, an amount of leakage current occurring in a turn-off state of the oxide semiconductor transistors may be smaller than that of the polysilicon semiconductor transistors.

A first electrode of the storage capacitor Cst may be connected to the first power line to which the first power voltage VDD is applied, and a second electrode of the storage capacitor Cst may be connected to the first node N1.

An anode electrode of the light emitting element LD may be connected to the fourth node N4, and a cathode electrode the light emitting element LD may be connected to the second power line to which the second power voltage VSS is applied. The light emitting element LD may be a light emitting diode. The light emitting element LD may include an organic light emitting diode, an inorganic light emitting diode, or a quantum dot/well light emitting diode. The light emitting element LD may emit light in one of a first color, a second color, or a third color. In addition, in the present embodiment, only one light emitting element LD is provided in each pixel, but in another embodiment, a plurality of light emitting elements may be provided in each pixel. In this case, the plurality of light emitting elements may be connected in series, in parallel, or in series/parallel with each other.

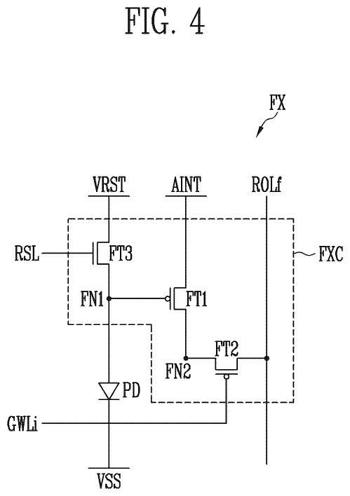

FIG. 4 is a drawing illustrating an optical sensor according to an embodiment of the present disclosure.

Referring to FIG. 4, the light sensor FX may include a sensor circuit FXC and a light-receiving element PD. The sensor circuit FXC may include sensing transistors FT1 to FT3. The sensor circuit FXC may be connected to an anode electrode of the light-receiving element PD and a first node FN1.

A first electrode of the first sensing transistor FT1 (e.g., an amplification transistor) may be connected to a second initialization line to which a second initialization voltage AINT is applied, a second electrode of the first sensing transistor FT1 may be connected to a second node FN2, and a gate electrode of the first sensing transistor FT1 may be connected to the first node FN1. The first sensing transistor FT1 may control a sensing current flowing through the first sensing transistor FT1 in response to a voltage of the first node FN1. The sensing current may be supplied to a readout line ROLf as a sensing signal via the second sensing transistor FT2. The first node FN1 may be referred to as a sensing node.

A first electrode of the second sensing transistor FT2 (e.g., an output transistor) may be connected to the second node FN2, a second electrode of the second sensing transistor FT2 may be connected to the readout line ROLf, and a gate electrode of the second sensing transistor FT2 may be connected to a first scan line GWLi. In other words, the same scan line (e.g., the first scan line GWLi) may be connected to the gate electrode of the second sensing transistor FT2 and the gate electrode of the second pixel transistor ST2. The second sensing transistor FT2 may be turned on when the first scan signal at the turn-on level is supplied to the first scan line GWLi to electrically connect the second electrode of the first sensing transistor FT1 and the readout line ROLf to each other.

A first electrode of the third sensing transistor FT3 (e.g., a reset transistor) may be connected to a reset voltage line to which a reset voltage VRST is applied, a second electrode of the third sensing transistor FT3 may be connected to the first node FN1, and a gate electrode of the third sensing transistor FT3 may be connected to the reset line RSL. The optical sensor FX may reset a voltage of a sensing node e.g., the first node FN1) in response to the reset signal received from the reset line RSL. The third sensing transistor FT3 may be turned on when a reset signal at the turn-on level is supplied to the reset line RSL to supply the reset voltage VRST to the first node FN1. The first node FN1, or in other words, the gate electrode of the first sensing transistor FT1, may be reset by the reset voltage VRST. The reset voltage VRST may be lower than the second power voltage VSS.

Some transistors FT1 and FT2 of the sensing transistors FT1 to FT3 may be P-type transistors, and other transistor FT3 thereof may be an N-type transistor, but the present disclosure is not limited thereto. For example, each of the sensing transistors FT1 to FT3 may be a P-type transistor or an N-type transistor.

A first electrode (e.g., an anode electrode) of the light-receiving element PD may be connected to the first node FN1, and a second electrode (e.g., a cathode electrode) of the light-receiving element PD may be connected to the second power line to which the second power voltage VSS is applied. The light-receiving element PD may be a photodiode. In another embodiment, the light-receiving element PD may be a photo transistor. When the light-receiving element PD receives light, electrons are excited, which allow a current to flow in the reverse direction from the cathode electrode to the anode electrode. Accordingly, when the light-receiving element PD is exposed to light, the voltage of the first node FN1 may gradually increase after the reset time point. As the light-receiving time increases or the amount of received light increases, the amount of increase in the voltage of the first node FN1 after the reset time point may increase. Accordingly, the amount of the sensing current flowing through the readout line ROLf may vary according to the light-receiving time and the amount of received light.

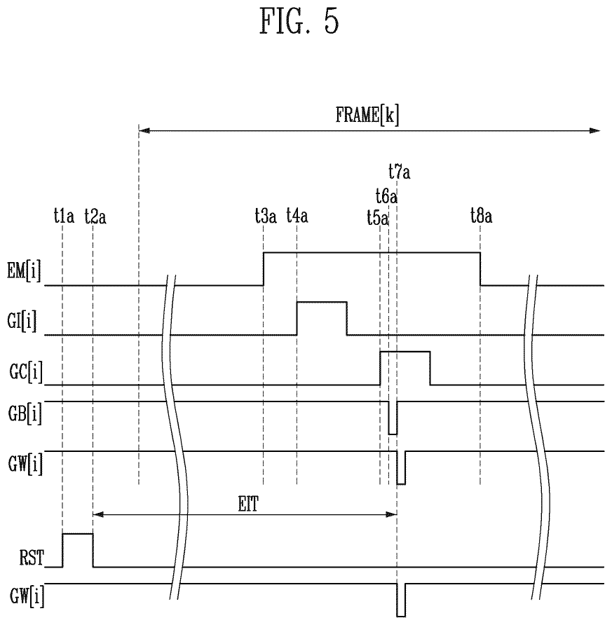

FIG. 5 is a drawing illustrating a method of driving a pixel and an optical sensor according to an embodiment of the present disclosure.

FIG. 5 illustrates a process in which the pixel PX of FIG. 3 and the optical sensor FX of FIG. 4 operate in an arbitrary k-th frame period FRAME[k].

First, the reset signal RST at the turn-on level may be applied to the reset line RSL during a period (e.g., t1a to t2a) before the k-th frame period FRAME[k]. Accordingly, the first node FN1 of the optical sensor FX may be reset by the reset voltage VRST. After the time point t2a, the voltage of the first node FN1 may gradually increase according to the length of the light-receiving period EIT and the amount of received light.

At the time point t3a, the emission signal EM[i] at the turn-off level is supplied to the emission line EMLi. Accordingly, the fifth pixel transistor ST5 and the sixth pixel transistor ST6 are turned off, and the light emitting element LD is prevented or substantially prevented from emitting light.

At the time point t4a, the third scan signal GI[i] at the turn-on level is supplied to the third scan line GILi. Accordingly, the fourth pixel transistor ST4 is turned on, and the first node N1 is initialized to the first initialization voltage VINT.

At the time point t5a, the second scan signal GC[i] at the turn-on level is supplied to the second scan line GCLi. Accordingly, the third pixel transistor ST3 is turned on, and the first pixel transistor ST1 is diode-connected.

At the time point t6a, the fourth scan signal GB[i] at the turn-on level is supplied to the fourth scan line GBLi. Accordingly, the seventh pixel transistor ST7 is turned on, and the fourth node N4 is initialized to the second initialization voltage AINT. The second initialization voltage AINT may have (e.g., may be set to) a voltage equal to or lower than that of the second power voltage VSS to express a low grayscale (e.g., a low gray level) of the light emitting element LD. In addition, the eighth pixel transistor ST8 is turned on, and the second node N2 is initialized to the bias voltage VOBS.

At the time point t7a, the first scan signal GW[i] at the turn-on level is supplied to the first scan line GWLi. Accordingly, the second pixel transistor ST2 is turned on, and a data voltage is applied to the second node N2. In this case, the first node N1 may be in a state in which the first initialization voltage VINT is applied, and the first initialization voltage VINT may be a voltage that is sufficiently lower than those of the data voltages. Accordingly, the first pixel transistor ST1 may be turned on, and a correction data voltage reflecting a threshold voltage reduction in the data voltage may be applied to the first node N1. The storage capacitor Cst maintains or substantially maintains a voltage corresponding to a difference between the first power supply voltage VDD and the compensated data voltage. This period may be referred to as a threshold voltage compensation period or a data writing period.

In addition, at the time point t7a, the second sensing transistor FT2 is turned on by the first scan signal GW[i] at the turn-on level. Accordingly, a sensing current corresponding to the light-receiving period EIT and the amount of received light may flow through the readout line ROLf.

At the time point t8a, the emission signal EM[i] at the turn-on level is supplied to the emission line EMLi. Accordingly, the fifth pixel transistor ST5 and the sixth pixel transistor ST6 are turned on, and the light emitting element LD may be in a state capable of emitting light.

In this case, a driving current path connecting the first power line, the fifth pixel transistor ST5, the first pixel transistor ST1, the sixth pixel transistor ST6, the light emitting element LD, and the second power line to each other is formed. The amount of driving current flowing through the first electrode and the second electrode of the first pixel transistor ST1 is adjusted according to the voltage maintained in the storage capacitor Cst. The light emitting element LD emits light having a luminance corresponding to the amount of driving current. The light emitting element LD may emit light until the emission signal EM[i] at the turn-off level is applied to the emission line EMLi.

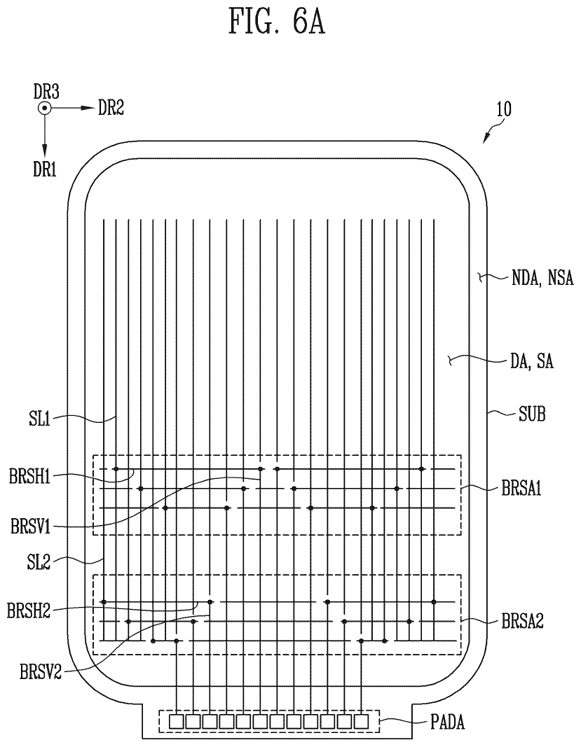

FIG. 6A and FIG. 6B are drawings illustrating a relationship between pads, connection lines, and signal lines according to one or more embodiments of the present disclosure.

Referring to FIG. 6A, a substrate SUB of the display panel 10 may include a display area DA and a non-display area NDA. The display area DA may be an area in which the pixels PX are disposed, and the non-display area NDA may be an area in which the pixels PX are not disposed. In addition, the substrate SUB may include a sensing area SA and a non-sensing area NSA. The sensing area SA may be an area in which the optical sensors FX are disposed, and the non-sensing area NSA may be an area in which the optical sensors FX are not disposed.

For example, the size and the shape of the display area DA may be the same or substantially the same as the size and the shape of the sensing area SA. In addition, the size and the shape of the non-display area NDA may be the same or substantially the same as the size and the shape of the non-sensing area NSA. However, the present disclosure is not limited thereto, and in another embodiment, the sensing area SA may be larger or smaller than the display area DA. According to the size of the sensing area SA, the non-sensing area NSA may be smaller or larger than the non-display area NDA.

Hereinafter, a planar direction of the substrate SUB is defined based on the first direction DR1 and the second direction DR2 crossing (e.g., perpendicular to or substantially perpendicular to) the first direction DR1. A vertical direction of the substrate SUB is defined based on the third direction DR3. However, the present disclosure is not limited thereto, and the substrate SUB may be curved. For example, a protruding portion of the substrate SUB in the first direction DR1 may include a pad area PADA, and the protruding portion may be bent to minimize or reduce a dead space. In addition, by bending other side surfaces of the substrate SUB, the display device DD including a narrower bezel that minimizes or reduces the non-display area NDA may be implemented.

The substrate SUB may include a first connection area BRSA1 and a second connection area BRSA2. The first connection area BRSA1 and the second connection area BRSA2 may commonly include signal lines SL1 and SL2 and first connection lines BRSV1 and BRSV2, each extending in the first direction DR1. The first connection area BRSA1 may include second connection lines BRSH1 extending in the second direction DR2. The second connection area BRSA2 may include second connection lines BRSH2 extending in the second direction DR2.

The signal lines SL1 and SL2 may include the data lines DL1 to DLm and the readout lines ROL1 to ROLr (e.g., see FIG. 1). The signal lines SL1 and SL2 may continuously extend in the first direction DR1 without being disconnected in the middle thereof.

The first connection lines BRSV1 and BRSV2 and the second connection lines BRSH1 and BRSH2 may be disconnected at a middle point thereof as needed or desired. The first connection lines BRSV1 and BRSV2 and the second connection lines BRSH1 and BRSH2 are connected to corresponding pads in the pad area PADA, thereby transmitting signals to the signal lines SL1 and SL2.

The edge of the substrate SUB may have an angular shape, but the present disclosure is not limited thereto, and the edge of the substrate SUB may have a curved shape as shown in FIG. 6A. The curved edge may make it difficult to implement an existing fan-out wiring structure. The second connection area BRSA2 according to the present embodiment may enable a fan-out free structure.

The first connection area BRSA1 may be a readout connection area. For example, the second connection lines BRSH1 of the first connection area BRSA1 may be the second readout connection lines connected to the readout lines ROL1 to ROLr of the optical sensors FX (e.g., see FIG. 1). For example, the first signal lines SL1 may be the readout lines ROL1 to ROLr. In this case, the first connection lines BRSV1 connected to the second connection lines BRSH1 in the first connection area BRSA1 may be the first readout connection lines. One of the readout lines, one of the first readout connection lines, and one of the second readout connection lines may be connected to each other. The order of the connection is not particularly limited, and as used herein, the phrase “connected to each other” may mean connected to the “same electrical node” as each other. Wires that are connected to the same electrical node as each other may have the same voltage as each other. The first connection lines BRSV1 are connected to corresponding pads, so that the first connection lines BRSV1 may transmit the sensing currents received from the optical sensors FX to an integrated chip (IC) that is connected to the pads.

In addition, the second connection area BRSA2 may be a data connection area. For example, the second connection lines BRSH2 of the second connection area BRSA2 may be the second data connection lines connected to the data lines DL1 to DLm of the pixels PX (e.g., see FIG. 1). For example, the second signal lines SL2 may be the data lines DL1 to DLm. In this case, the first connection lines BRSV2 connected to the second connection lines BRSH2 in the second connection area BRSA2 may be the first data connection lines. One of the data lines, one of the first data connection lines, and one of the second data connection lines may be connected to each other. The order of the connection is not particularly limited, and as used herein, the phrase “connected to each other” may mean connected to the “same electrical node” as each other. Wires that are connected to the same electrical node as each other may have the same voltage as each other. The first connection lines BRSV2 are connected to the corresponding pads, so that the first connection lines BRSV2 may transmit the data voltages received from the IC to the pixels PX.

In FIG. 6A, the second connection area BRSA2 is illustrated as being disposed in the first direction DR1 from the first connection area BRSA1. However, the present disclosure is not limited thereto. As another example, the first connection area BRSA1 may be disposed in the first direction DR1 from the second connection area BRSA2.

In some embodiments, the first connection area BRSA1 and the second connection area BRSA2 may not be spaced apart from each other in the first direction DR1. Referring to FIG. 6B, the first connection area BRSA1 and the second connection area BRSA2 may be spaced apart from each other in the second direction DR2.

In another embodiment, there may be no distinction between the first connection area BRSA1 and the second connection area BRSA2. For example, because the second readout connection line and the second data connection line may be alternately disposed along the first direction DR1, the distinction between the readout connection area and the data connection area may not be readily apparent.

In some embodiments, the display device DD may further include an additional sensor layer on an upper portion of a layer in which the pixels PX and the optical sensors FX are formed (e.g., in the third direction DR3). The additional sensor layer may be a sensor layer for sensing a user's touch and/or an active pen, and may be configured in various suitable ways, such as a resistive type, a capacitive type, an electro-magnetic induction type (EMI), an electro-magnetic resonance type (EMR), and/or an optical type. In another embodiment, the additional sensor layer may be disposed below the layer on which the pixels PX and the optical sensors FX are formed (e.g., in a direction opposite to the third direction DR3).

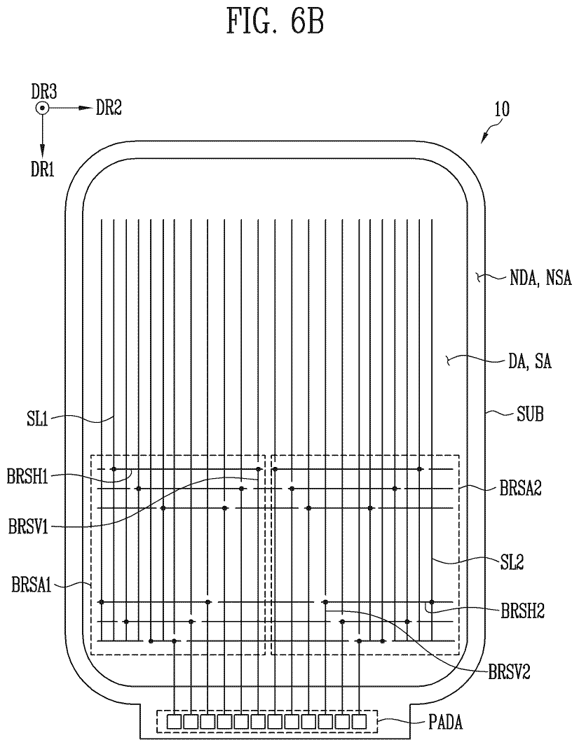

FIG. 7 is a drawing illustrating a stacked structure of a display area of a display panel.

Referring to FIG. 7, the display panel 10 may have a structure in which a substrate SUB, a first insulating layer INL1, a first active layer ACL1, a second insulating layer INL2, a first electrode layer CEL1, a third insulating layer INL3, a second electrode layer CEL2, a fourth insulating layer INL4, a second active layer ACL2, a fifth insulating layer INL5, a third electrode layer CEL3, a sixth insulating layer INL6, a fourth electrode layer CEL4, a seventh insulating layer INL7, a fifth electrode layer CEL5, an eighth insulating layer INL8, and a sixth electrode layer CEL6 are sequentially stacked on one another.

A stacked structure of the pixel circuit PXC and the sensor circuit FXC in the display area DA or the sensing area SA will be described in more detail below with reference to FIG. 7 through FIG. 22. Any suitable method known to those having ordinary skill in the art may be used for forming the stacked structure of the light emitting element LD and the light-receiving element PD.

The substrate SUB may include (e.g., may be made of) various suitable materials, such as glass, a polymer, and/or a metal. The substrate SUB may be one of a rigid substrate or a flexible substrate, depending on the desired product to which it is applied. When the substrate SUB includes a polymer organic material, the substrate SUB may include polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, or cellulose acetate propionate. In some embodiments, the substrate (SUB) may include (e.g., may be made of) glass, fiber glass reinforced plastic (FRP), or the like.

The first active layer ACL1 and the second active layer ACL2 may be semiconductor layers. For example, the first active layer ACL1 may be formed of a polysilicon semiconductor, and the second active layer ACL2 may be formed of an oxide semiconductor. The first active layer ACL1 may include a channel CH1, a first electrode E11, and a second electrode E12 of the polysilicon semiconductor transistors TR1 (e.g., ST2, ST5, ST6, ST7, ST8, FT1, and FT2). The second active layer ACL2 may include a channel CH2, a first electrode E21, and a second electrode E22 of the oxide semiconductor transistors TR2 (e.g., ST3, ST4, and FT3). The first electrode and the second electrode of each transistor may be doped with impurities to become conductors.

A gate electrode GE1 of the polysilicon semiconductor transistor TR1 may be disposed at (e.g., in or on) the first electrode layer CEL1. In some embodiments, a sub-gate electrode (e.g., a back gate electrode or a body electrode) of the polysilicon semiconductor transistor TR1 may be disposed between the substrate SUB and the first insulating layer INL1.

A gate electrode GE2 of the oxide semiconductor transistor TR2 may be disposed at (e.g., in or on) the third electrode layer CEL3. In some embodiments, a sub-gate electrode (e.g., a back gate electrode or a body electrode) of the oxide semiconductor transistor TR2 may be disposed at (e.g., in or on) the second electrode layer CEL2.

The first electrode layer CEL1, the second electrode layer CEL2, the third electrode layer CEL3, the fourth electrode layer CEL4, the fifth electrode layer CEL5, and the sixth electrode layer CEL6 may be conductive layers. Each electrode layer may be a single layer or multilayers, and may include (e.g., may be made of) a conductive material, such as gold (Au), silver (Ag), aluminum (Al), molybdenum (Mo), chromium (Cr), titanium (Ti), nickel (Ni), neodymium (Nd), copper (Cu), or platinum (Pt).

The first insulating layer INL1, the second insulating layer INL2, the third insulating layer INL3, the fourth insulating layer INL4, the fifth insulating layer INL5, the sixth insulating layer INL6, the seventh insulating layer INL7, and the eighth insulating layer INL8 may be interposed to electrically separate the active layers ACL1 and ACL2 and the first to sixth electrode layers CEL1, CEL2, CEL3, CEL4, CEL5, and CEL6 from one another. Electrode patterns may be connected to each other through contact holes formed in the insulating layers INL1 to INL8. The insulating layers INL1 to INL8 may be formed of an organic insulating film, an inorganic insulating film, or an organic/inorganic insulating film, and may be formed of a single layer or multilayers. For example, the insulating layers INL1 to INL8 may include at least one of silicon nitride (SiNx), silicon oxide (SiOx), silicon oxynitride (SiOxNy), an acrylic resin, an epoxy resin, a phenolic resin, a polyamide resin, or a polyimide resin.

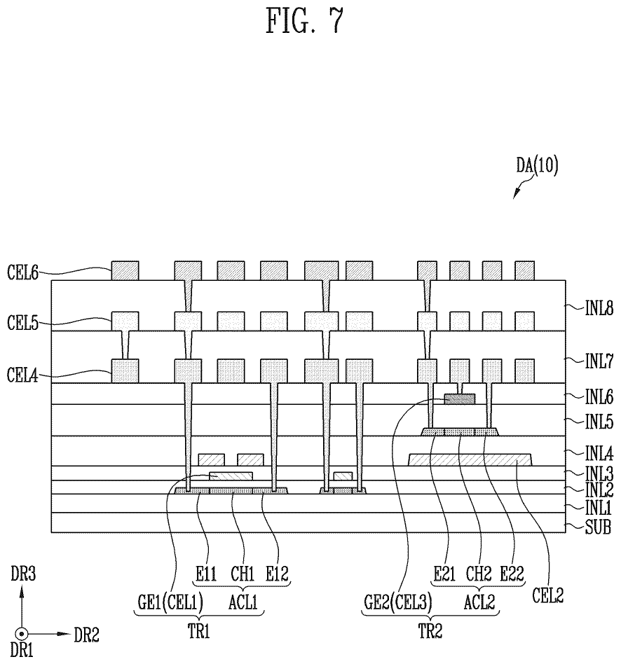

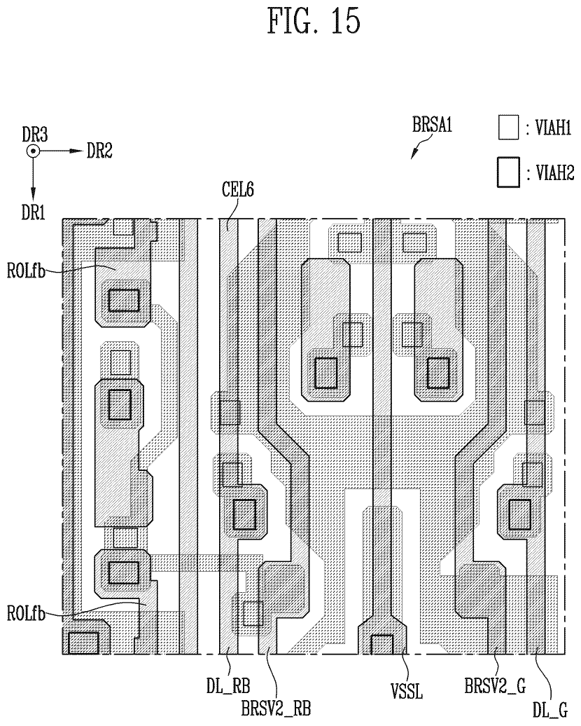

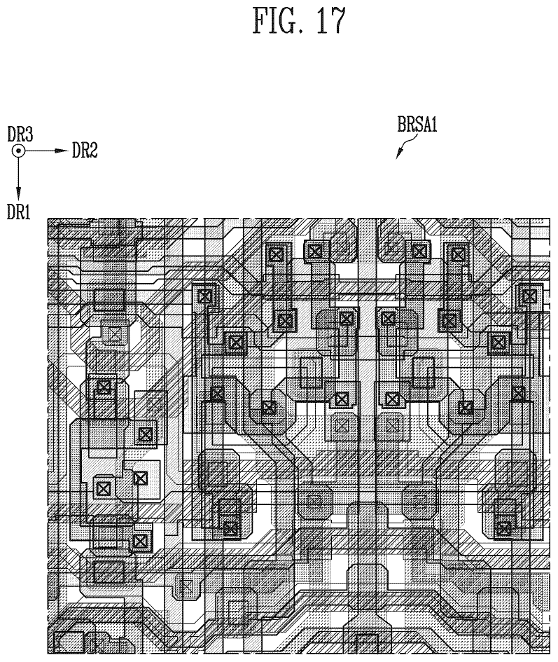

FIG. 8 through FIG. 17 are drawings illustrating a plan layout of a first connection area according to one or more embodiments of the present disclosure. FIG. 18 illustrates a cross-sectional view taken along the line I-I′ of FIG. 16.

Referring to FIG. 8, the first active layer ACL1 is illustrated as an example. The first active layer ACL1 may include channels ST1c, ST2c, ST5c, ST6c, ST7c, ST8c, FT1c, and FT2c of the transistors ST1, ST2, ST5, ST6, ST7, ST8, FT1, and FT2. Portions of the first active layer ACL1 that are spaced apart from each other with a channel therebetween may configure the first electrode and the second electrode of the transistors ST1, ST2, ST5, ST6, ST7, ST8, FT1, and FT2, respectively.

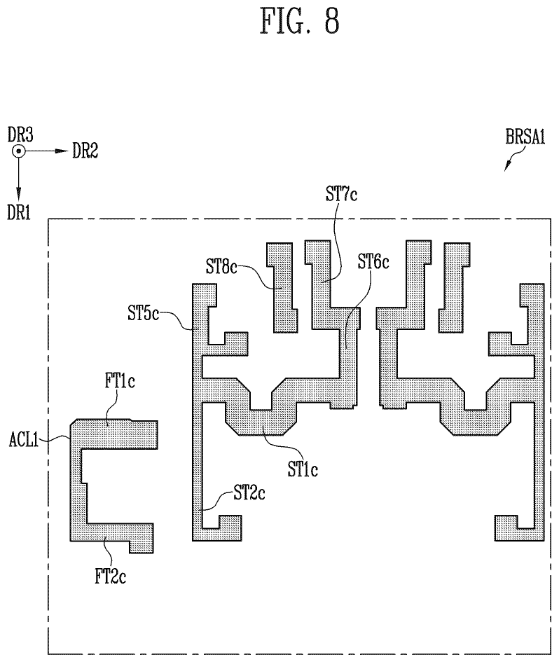

Referring to FIG. 9, example patterns of the first electrode layer CEL1 are further illustrated. The first electrode layer CEL1 may include gate electrodes ST1g, ST2g, ST5g, ST6g, ST7g, ST8g, FT1g, and FT2g of the transistors ST1, ST2, ST5, ST6, ST7, ST8, FT1, and FT2. The gate electrodes ST1g, ST2g, ST5g, ST6g, ST7g, ST8g, FT1g, and FT2g may overlap with the corresponding channels ST1c, ST2c, ST5c, ST6c, ST7c, ST8c, FT1c, and FT2c in the third direction DR3.

In addition, some patterns of the first electrode layer CEL1 may configure the first scan line GWLi, the fourth scan line GBLi, the emission line EMLi, and the second electrode Cst2e of the storage capacitor Cst.

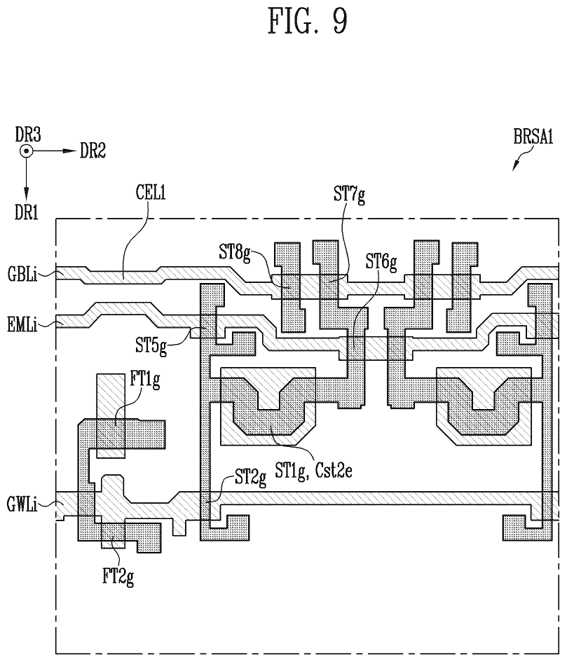

Referring to FIG. 10, example patterns of the second electrode layer CEL2 are further illustrated. The second electrode layer CEL2 may include sub-gate electrodes ST3ga, ST4ga, and FT3ga of the transistors ST3, ST4, and FT3.

In addition, some patterns of the second electrode layer CEL2 may configure the sub-reset line RSLa, the third sub-scan line GILia, the second sub-scan line GCLia, and the first electrode Cst1e of the storage capacitor Cst.

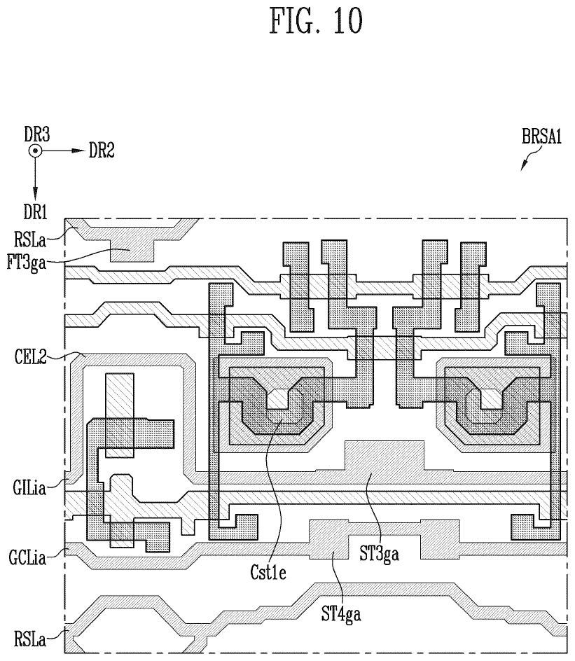

Referring to FIG. 11, example patterns of the second active layer ACL2 are further illustrated. The second active layer ACL2 may include channels ST3c, ST4c, and FT3c of the transistors ST3, ST4, and FT3. The channels ST3c, ST4c, and FT3c may overlap with the corresponding sub-gate electrodes ST3ga, ST4ga, and FT3ga in the third direction DR3. Portions of the second active layer ACL2 that are spaced apart from each other with a channel therebetween may configure the first electrode and the second electrode of the transistors ST3, ST4, and FT3, respectively.

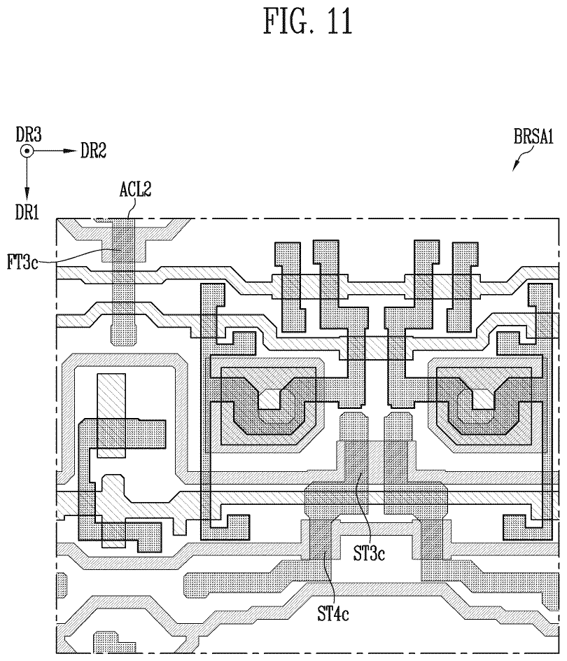

Referring to FIG. 12, example patterns of the third electrode layer CEL3 are further illustrated. The third electrode layer CEL3 may include the gate electrodes ST3gb, ST4gb, and FT3gb of the transistors ST3, ST4, and FT3. The gate electrodes ST3gb, ST4gb, and FT3gb may overlap with the corresponding channels ST3c, ST4c, and FT3c in the third direction DR3.

In addition, some patterns of the third electrode layer CEL3 may configure the reset line RSLb, the third scan line GILib, the second scan line GCLib, the (2-1)-th initialization line AINTL_R, and the (2-2)-th initialization line AINTL_GB. The second initialization voltage AINT may be applied to the (2-1)-th initialization line AINTL_R and the (2-2)-th initialization line AINTL_GB (e.g., see FIG. 3 and FIG. 4). However, the (2-1)-th initialization line AINTL_R may be connected to pixels including the light emitting element R of the first color, and the (2-2)-th initialization line AINTL_GB may be connected to pixels including the light emitting element G or B of the second color or the third color. For example, the second initialization voltage AINT applied to the (2-1)-th initialization line AINT_R and the second initialization voltage AINT applied to the (2-2)-th initialization line AINT_GB may be the same or substantially the same as each other or may be different from each other. Whether or not the second initialization voltages AINT are the same or substantially the same as each other may be variously modified depending on the characteristics of the light emitting elements R, G, and B.

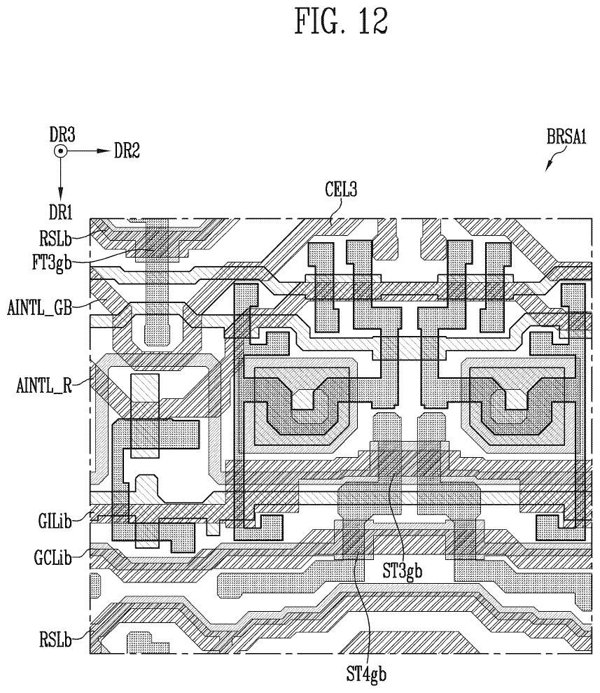

Referring to FIG. 13, example patterns of the fourth electrode layer CEL4 are further illustrated. Some patterns of the fourth electrode layer CEL4 may include the reset voltage line VRSTL, the bias line VOBSL, the first initialization line VINTL, and the second connection line BRSH1.

The reset voltage VRST may be applied to the reset voltage line VRSTL (e.g., see FIG. 4). The bias voltage VOBS may be applied to the bias line VOBSL (e.g., see FIG. 3). The first initialization voltage VINT may be applied to the first initialization line VINTL (e.g., see FIG. 3). As described above with reference to FIG. 6A and FIG. 6B, the second connection line BRSH1 disposed in the first connection region BRSA1 may be the second readout connection line.

First contact holes PCTH may be holes that are etched to connect the patterns of the fourth electrode layer CEL4 to the electrode layer therebelow or the first active layer ACL1. Second contact holes OCTH may be holes that are etched to connect the patterns of the fourth electrode layer CEL4 to the electrode layer therebelow or the second active layer ACL2.

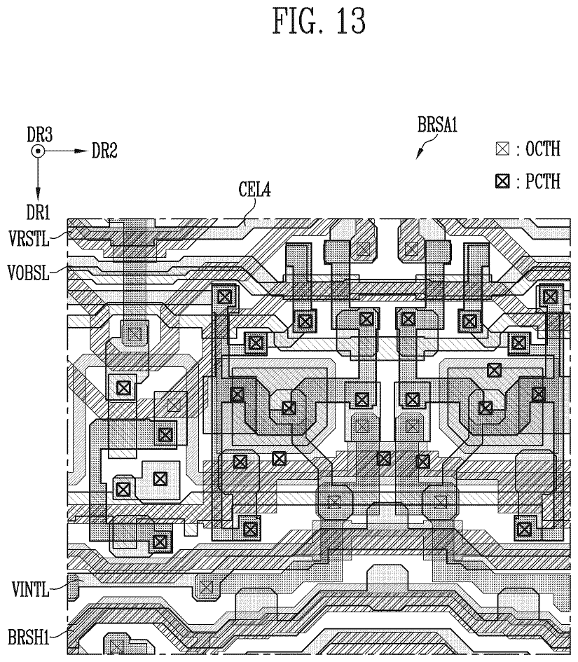

Referring to FIG. 14, example patterns of the fifth electrode layer CEL5 are illustrated. Some patterns of the fifth electrode layer CEL5 may include the readout line pattern ROLfa, the first power line VDDL, and the first electrode pattern EPT1. The first power line VDDL and the first electrode pattern EPT1 may be integrally formed (e.g., integrally configured). The first power voltage VDD may be applied to the first power line VDDL.

Third contact holes VIAH1 may be holes that are etched to connect the patterns of the fifth electrode layer CEL5 to the electrode layer therebelow or the active layer.

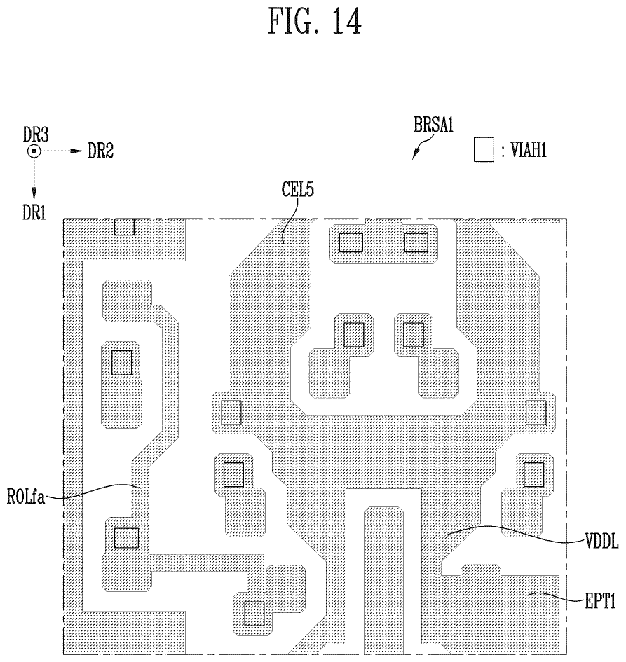

Referring to FIG. 15, example patterns of the sixth electrode layer CEL6 are further illustrated. Some patterns of the sixth electrode layer CEL6 may include the readout line pattern ROLfb, the data lines DL_RB and DL_G, the first connection lines BRSV2_RB and BRSV2_G, and the second power line VSSL. The second power voltage VSS may be applied to the second power line VSSL.

The data line DL_RB may be connected to pixels including the light emitting element R or B of the first color or the third color, and the data line DL_G may be connected to pixels including the light emitting element G of the second color. As described above with reference to FIG. 6A and FIG. 6B, the first connection lines BRSV2_RB and BRSV2_G may be the first data connection lines. For example, the first connection line BRSV2_RB may receive data voltages corresponding to pixels including the light emitting element R or B of the first color or the third color from the connected pad. The second connection line BRSV2_G may receive data voltages corresponding to pixels including the light emitting element G of the second color from the connected pad.

Fourth contact holes VIAH2 may be holes that are etched to connect the patterns of the sixth electrode layer CEL6 to the electrode layer therebelow or the active layer.

Referring to FIG. 16, the patterns of the fourth electrode layer CEL4, the fifth electrode layer CEL5, and the sixth electrode layer CEL6 are illustrated to overlap with each other.

The readout line pattern ROLfb may be connected to the readout line pattern ROLfa to form the readout line ROLf extending in the first direction DR1.

In addition, the readout line pattern ROLfa may be connected to the second connection line BRSH1 through the third contact hole VIAH1_BRSH1. Accordingly, the second connection line BRSH1 may function as the second readout connection line that transmits the sensing signal.

The second readout connection line may overlap with at least one of the data line and/or the first data connection line in the first area. For example, the second connection line BRSH1 may overlap with the data line DL_G and the first connection line BRSV2_G in the first area AR1. In this case, the second connection line BRSH1 may form an undesirable parasitic capacitance with the data line DL_G and the first connection line BRSV2_G. Accordingly, the voltage level of the sensing signal flowing through the second connection line BRSH1 may be changed depending on a voltage change of the data line DL_G and the first connection line BRSV2_G. When the sensing signal is changed, the sensing information may become inaccurate.

According to one or more embodiments of the present disclosure, the first electrode pattern may be disposed between at least one of the data line and/or the first data connection line and the second readout connection line in the first area. For example, the first electrode pattern EPT1 may be disposed between the data line DL_G and the second connection line BRSH1 in the first area AR1. In addition, the first electrode pattern EPT1 may be disposed between the first connection line BRSV2_G and the second connection line BRSH1 in the first area AR1.

Referring to FIG. 18, a cross-sectional view of the display panel 10 taken along the line I-I′ of the first area AR1 is illustrated as an example. In the third direction DR3, the first electrode pattern EPT1 may shield the second connection line BRSH1 from the data line DL_G and the first connection line BRSV2_G. The first electrode pattern EPT1 to which the first power voltage VDD is applied may prevent or substantially prevent the formation of a parasitic capacitance between the data line DL_G and the second connection line BRSH1. In addition, the first electrode pattern EPT1 to which the first power voltage VDD is applied may prevent or substantially prevent the formation of a parasitic capacitance between the first connection line BRSV2_G and the second connection line BRSH1. Accordingly, even if the voltages of the data line DL_G and the first connection line BRSV2_G are changed, the voltage level of the sensing signal flowing through the second connection line BRSH1 may not be affected.

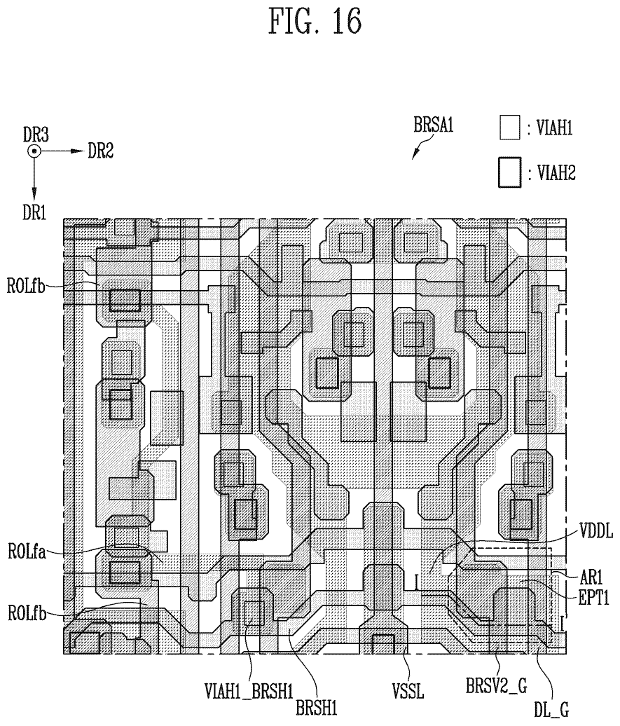

In FIG. 17, a layout in which the first active layer ACL1, the first electrode layer CEL1, the second electrode layer CEL2, the second active layer ACL2, the third electrode layer CEL3, the fourth electrode layer CEL4, the fifth electrode layer CEL5, and the sixth electrode layer CEL6 overlap with each other is shown.

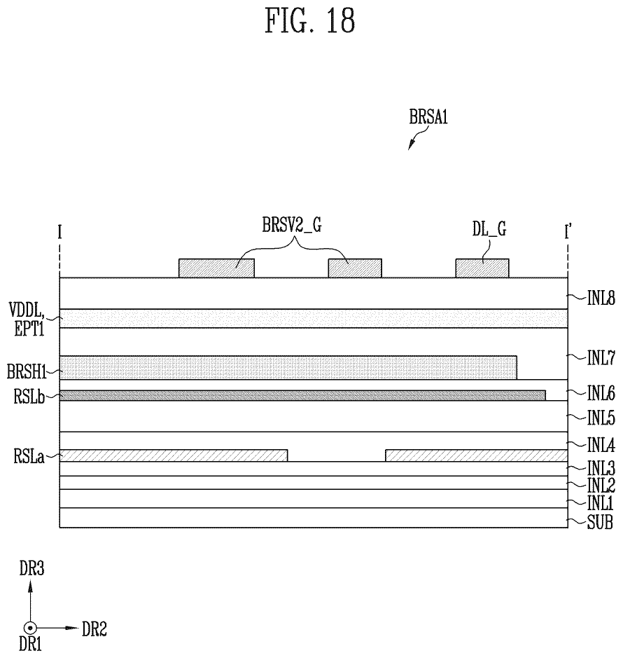

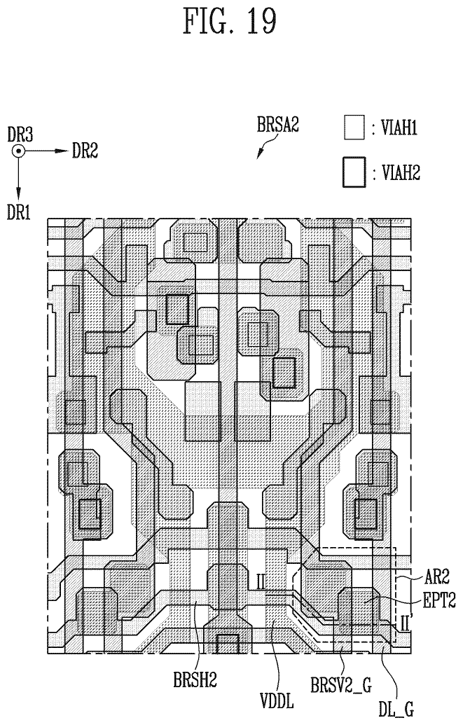

FIG. 19 is a drawing illustrating a plan layout of a second connection area according to an embodiment of the present disclosure. FIG. 20 illustrates a cross-sectional view taken along the line II-II′ of FIG. 19.

Referring to FIG. 19 and FIG. 20, the display panel 10 may further include a second electrode pattern EPT2 in the second connection area BRSA2. As described above with reference to FIG. 6A and FIG. 6B, the second connection line BRSH2 of the second connection area BRSA2 may function as the second data connection line to which a data voltage is applied.

The second data connection line may overlap with at least one of the data line and/or the first data connection line in the second area. For example, the second connection line BRSH2 may overlap with the data line DL_G and the first connection line BRSV2_G in the second area AR2. In this case, the second connection line BRSH2 may form a parasitic capacitance with the data line DL_G and the first connection line BRSV2_G. However, because the data voltage is applied to the second connection line BRSH2, the data line DL_G, and the first connection line BRSV2_G, a negative effect of the parasitic capacitance may be relatively small. For example, the signal levels in the second connection line BRSH2, the data line DL_G, and the first connection line BRSV2_G may change at the same or substantially the same time as each other, so that noise on the signal level before and after the change may be minimized or reduced.

According to one or more embodiments of the present disclosure, the second electrode pattern may be disposed between at least one of the data line and/or the first data connection line and the second data connection line in the second area. For example, the second electrode pattern EPT2 may be disposed between the data line DL_G and the second connection line BRSH2 in the second area AR2. The second electrode pattern EPT2 may be disposed between the first connection line BRSV2_G and the second connection line BRSH2 in the second area AR2.

As described above, because the negative effect of the parasitic capacitance is relatively small, the second electrode pattern EPT2 may have an island shape that is not connected to other electrodes. In addition, a voltage may not be supplied to the second electrode pattern EPT2. As such, the second electrode pattern EPT2 may be a dummy pattern.

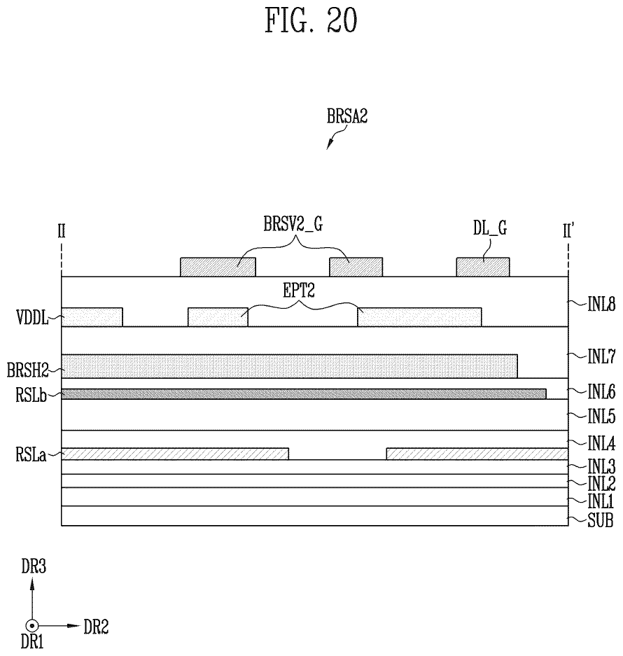

FIG. 21 is a drawing illustrating an example connection between a first data connection line and a second data connection line. The first connection line BRSV2_G may function as the first data connection line, and the second connection line BRSH2 may function as the second data connection line.

Referring to FIG. 21, the first connection line BRSV2_G may be connected to the second electrode pattern EPT2 through a fourth contact hole VIAH2_BRSV2_G. The second electrode pattern EPT2 may be connected to the second connection line BRSH2 through a third contact hole VIAH1_BRSH2.

The second electrode pattern EPT2 of FIG. 21 may be different from the second electrode pattern EPT2 of FIG. 20, in that the second electrode pattern EPT2 may serve as a bridge pattern connecting the first connection line BRSV2_G and the second connection line BRSH2 to each other. As described above, the second electrode pattern EPT2 may function as the bridge pattern in a portion of the second connection area BRSA2, and may remain as a dummy pattern in another portion of the second connection area BRSA2.

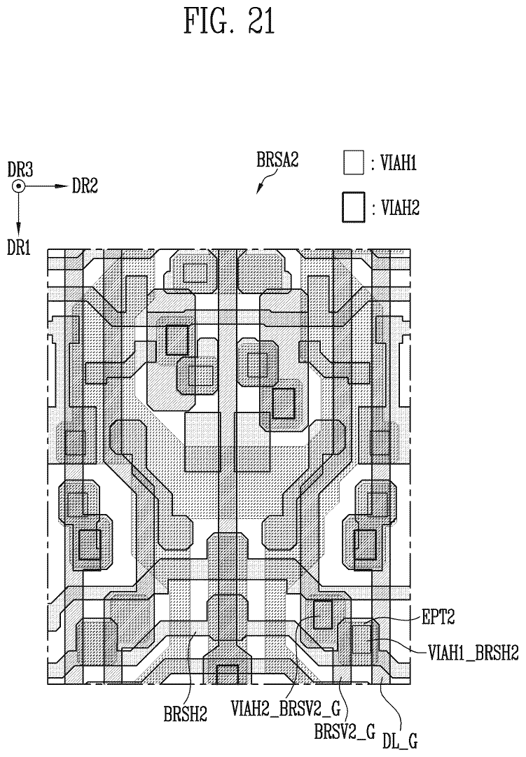

FIG. 22 is a drawing illustrating an example connection between a first readout connection line and a second readout connection line. The first connection line BRSV1 may function as the first readout connection line, and the second connection line BRSH1 may function as the second readout connection line.

Referring to FIG. 22, the electrode pattern that functions as the second power line VSSL in FIG. 16 may function as the first connection line BRSV1 in FIG. 22. The first connection line BRSV1 may be the first readout connection line.

According to one or more embodiments of the present disclosure, the first data connection line may have a first interval in the second direction DR2 from the closest data line. The first readout connection line may have a second interval in the second direction DR2 from the closest data line. In this case, the second interval may be larger than the first interval.

For example, the first connection line BRSV2_G may have the first interval in the second direction DR2 from the closest data line DL_G. The first connection line BRSV1 may have the second interval in the second direction DR2 from the closest data line DL_G or DL_RB. In this case, the second interval may be larger than the first interval.

According to one or more embodiments of the present disclosure, the first readout connection line may be disposed between two adjacent pixels to be configured in a mirror-symmetrical layout. For example, the first connection line BRSV1 may be disposed between two adjacent pixels PX_L and PX_R in a mirror-symmetrical layout. The layout of FIG. 16 may minimize or reduce a dead space by supplying the second power voltage VSS that is common to the pixels PX_L and PX_R from one line. In the present embodiment, by functioning the electrode pattern that previously functioned as the second voltage line VSSL as the first connection line BRSV1, the horizontal separation distance between the first connection line BRSV1 and the first connection lines BRSV2_G and BRSV2_RB and the horizontal separation distance between the first connection line BRSV1 and the data lines DL_G and DL_RB may be maximized or reduced.

According to the present embodiment, the first connection line BRSV1 may be sufficiently spaced apart from the first connection lines BRSV2_G and BRSV2_RB in a plan view. In addition, the first connection line BRSV1 may be sufficiently spaced apart from the data lines DL_G and DL_RB in a plan view. Accordingly, the formation of a parasitic capacitance between the first connection line BRSV1 and the first connection lines BRSV2_G and BRSV2_RB and the formation of a parasitic capacitance between the first connection line BRSV1 and the data lines DL_G and DL_RB may be minimized or reduced.

The cathode electrodes of the light emitting elements LD of the pixels PX may be connected to each other. Therefore, even if a portion of the second power line VSSL functions as the first connection line BRSV1, no issues may occur.

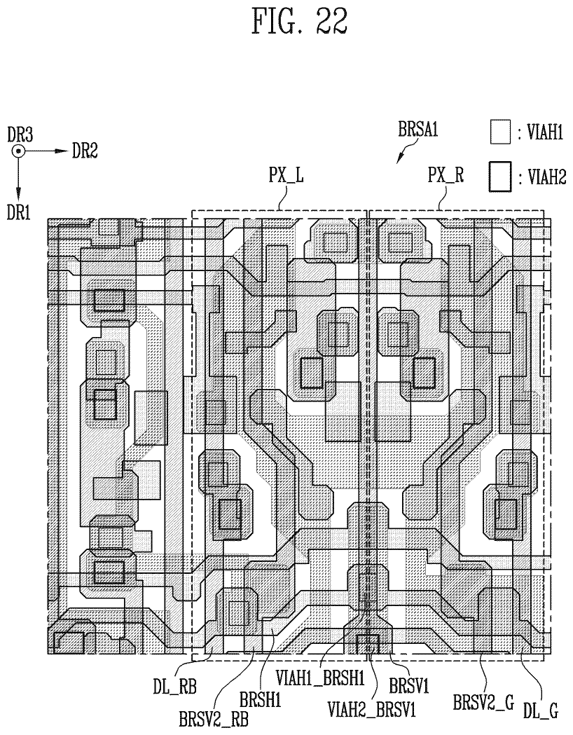

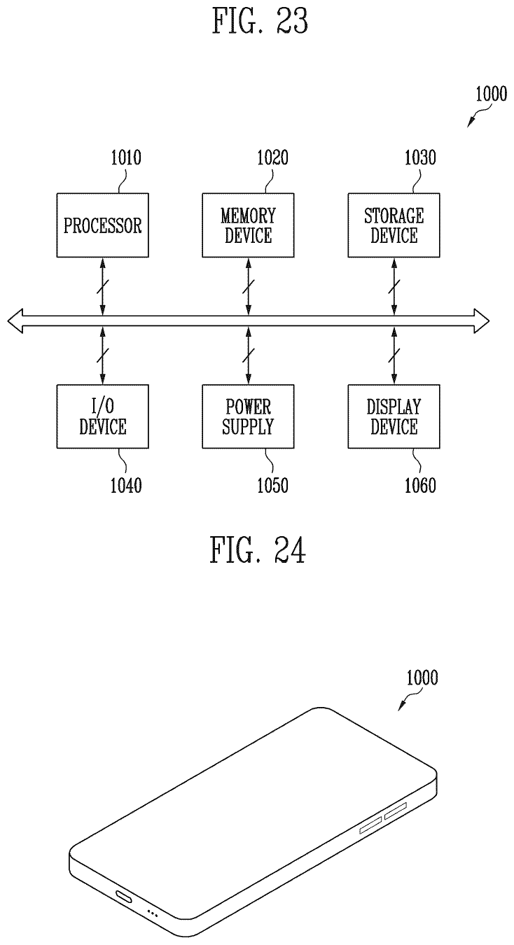

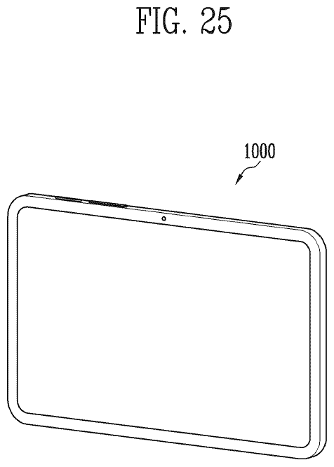

FIG. 23 illustrates a block diagram of an electronic device according to one or more embodiments of the present disclosure. FIG. 24 illustrates an example in which the electronic device of FIG. 23 is implemented as a smart phone. FIG. 25 illustrates an example in which the electronic device of FIG. 23 is implemented as a tablet PC.

Referring to FIG. 23 through FIG. 25, an electronic device 1000 may include a processor 1010, a memory device 1020, a storage device 1030, an input/output device 1040, a power supply device 1050, and a display device 1060. In this case, the display device 1060 may be the display device DD described above with reference to FIG. 1. In addition, the electronic device 1000 may further include several ports capable of communicating with a video card, a sound card, a memory card, a USB device, and the like, or communicating with other systems. In an embodiment, as shown in FIG. 24, the electronic device 1000 may be implemented as a smart phone. In another embodiment, as shown in FIG. 25, the electronic device 1000 may be implemented as a tablet PC. However, the present disclosure is not limited thereto, and the electronic device 1000 may be implemented as a mobile phone, a video phone, a smart pad, a smart watch, a vehicle navigation, a computer monitor, a laptop, a head mounted display device, or the like.

The processor 1010 may perform specific calculations or tasks. In some embodiments, the processor 1010 may be a micro-processor, a central processing unit, an application processor, or the like. The processor 1010 may be connected to other constituent elements through an address bus, a control bus, and a data bus. In some embodiments, the processor 1010 may also be connected to an extension bus, such as a peripheral component interconnect (PCI) bus.

The memory device 1020 may store data used for operations of the electronic device 1000. For example, the memory device 1020 may include non-volatile memory devices, such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, and/or a ferroelectric random access memory (FRAM) device, and/or volatile memory devices, such as a dynamic random access memory (DRAM) device, a static random access memory (SRAM) device, and/or a mobile DRAM device.

The storage device 1030 may include a solid state drive (SSD), a hard disk drive (HDD), a CD-ROM, and/or the like.

The input/output device 1040 may include input devices, such as a keyboard, a keypad, a touch pad, a touchscreen, mouse, and/or the like, and output devices, such as a speaker, a printer, and/or the like. In some embodiments, the display device 1060 may be included in the input/output device 1040.

The power supply 1050 may supply power used for the operation of the electronic device 1000. For example, the power supply 1050 may be a power management integrated circuit (PMIC).

The display device 1060 may display an image corresponding to visual information of the electronic device 1000. In this case, the display device 1060 may be an organic light emitting display device or a quantum dot light emitting display device, but the present disclosure is not limited thereto. The display device 1060 may be connected to other constituent elements through the buses or other communication links.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a pixel comprising a light-emitting element configured to receive a data voltage from a data line, and emit light having a luminance based on the data voltage;
an optical sensor comprising a light-receiving element, and configured to provide a sensing current generated based on an amount of light received by the light-receiving element to a readout line;
a plurality of first connection lines extending in a first direction, and comprising a first readout connection line and a first data connection line;
a plurality of second connection lines extending in a second direction different from the first direction, and comprising a second readout connection line; and
a first electrode pattern,
wherein the readout line, the first readout connection line, and the second readout connection line are connected to each other at a same electrical node,
wherein the data line and the first data connection line are connected to each other at a same electrical node,
wherein the second readout connection line overlaps with at least one of the data line or the first data connection line in a first area, and
wherein the first electrode pattern is located between at least one of the data line or the first data connection line and the second readout connection line in the first area.

2. The display device of claim 1, wherein the first electrode pattern is configured to receive a first power voltage supplied to the pixel.

3. The display device of claim 1, wherein the first electrode pattern is integral with a first power line connected to the pixel.

4. The display device of claim 3, wherein the first electrode pattern is not connected to the optical sensor.

5. The display device of claim 4, wherein the pixel and the optical sensor are connected to a same scan line.

6. The display device of claim 1, further comprising a second electrode pattern,
wherein the plurality of second connection lines further comprises a second data connection line,
wherein the second data connection line is connected to the data line and the first data connection line at a same electrical node, and the second data connection line overlaps with at least one of the data line or the first data connection line in a second area, and
wherein the second electrode pattern is located between at least one of the data line or the first data connection line and the second data connection line in the second area.

7. The display device of claim 6, wherein the second electrode pattern has an island shape that is not connected to other electrodes.

8. The display device of claim 7, wherein a voltage is not supplied to the second electrode pattern.

9. The display device of claim 1, wherein:
the first data connection line has a first interval from a closet data line thereto in the second direction;
the first readout connection line has a second interval from a closet data line thereto in the second direction; and
the second interval is greater than the first interval.

10. The display device of claim 1, wherein the first readout connection line is located between two adjacent pixels configured in a mirror-symmetrical layout.

11. A display device comprising:
a pixel comprising a light-emitting element configured to receive a data voltage from a data line, and emit light having a luminance based on the data voltage;
an optical sensor comprising a light-receiving element, and configured to provide a sensing current generated based on an amount of light received by the light-receiving element to a readout line;
a plurality of first connection lines extending in a first direction, and comprising a first readout connection line and a first data connection line; and
a plurality of second connection lines extending in a second direction different from the first direction, and comprising a second readout connection line,
wherein the readout line, the first readout connection line, and the second readout connection line are connected to each other at a same electrical node,
wherein the data line and the first data connection line are connected to each other at a same electrical node,
wherein the first data connection line has a first interval from a closet data line thereto in the second direction,
wherein the first readout connection line has a second interval from a closet data line thereto in the second direction, and
wherein the second interval is greater than the first interval.

12. The display device of claim 11, wherein the first readout connection line is located between two adjacent pixels configured in a mirror-symmetrical layout.

13. The display device of claim 11, further comprising a first electrode pattern,
wherein the second readout connection line overlaps with at least one of the data line or the first data connection line in a first area, and
wherein the first electrode pattern is located between at least one of the data line or the first data connection line and the second readout connection line in the first area.

14. The display device of claim 13, wherein the first electrode pattern is configured to receive a first power voltage supplied to the pixel.

15. The display device of claim 13, wherein the first electrode pattern is integral with a first power line connected to the pixel.

16. The display device of claim 15, wherein the first electrode pattern is not connected to the optical sensor.

17. The display device of claim 16, wherein the pixel and the optical sensor are connected to a same scan line.

18. The display device of claim 13, further comprising a second electrode pattern,
wherein the plurality of second connection lines further comprises a second data connection line,
wherein the second data connection line is connected to the data line and the first data connection line at a same electrical node,
wherein the second data connection line overlaps with at least one of the data line or the first data connection line in a second area, and
wherein the second electrode pattern is located between at least one of the data line or the first data connection line and the second data connection line in the second area.

19. The display device of claim 18, wherein the second electrode pattern has an island shape that is not connected to other electrodes.

20. The display device of claim 19, wherein a voltage is not supplied to the second electrode pattern.
